(19) United States
(12) Patent Application Publication
(10) Pub. No.: US 2024/0203993 A1
(43) Pub. Date: Jun. 20, 2024

(54) LOW RESISTANCE METALIZATION FOR CONNECTING A VERTICAL TRANSPORT FET SINGLE-CPP INVERTER

(71) Applicant: International Business Machines Corporation, Armonk, NY (US)

(72) Inventors: Brent A. Anderson, Jericho, VT (US); Nicholas Anthony Lanzillo, Wynantskill, NY (US); Albert M. Chu, Nashua, NH (US); Ruilong Xie, Niskayuna, NY (US); Lawrence A. Clevenger, Saratoga Springs, NY (US)

(21) Appl. No.: 18/065,663

(22) Filed: Dec. 14, 2022

(51) Int. Cl. H01L 27/092; H01L 23/498; H01L 29/08; H01L 29/10; H01L 29/66; H01L 29/78

(52) U.S. Cl. CPC H01L 27/0924; H01L 23/49844; H01L 29/0847; H01L 29/1033; H01L 29/66666; H01L 29/66795; H01L 29/7827; H01L 29/785

(57) ABSTRACT

Embodiments of the invention provide a multi-layer integrated circuit (IC) structure that includes a first transistor, a second transistor, and a contact element. The first transistor includes a first source or drain (S/D). The second transistor includes a second S/D and a gate. The contact element includes substantially horizontal features operable to connect the first S/D of the first transistor to the gate of the second transistor.

### BACKGROUND

The present invention generally relates to fabrication methods and resulting structures for integrated circuit (IC) wafers. More specifically, the present invention relates to fabrication methods and resulting structures for providing a low resistance metallization scheme for connecting a single-CPP vertical transport field effect transistor (VTFET) inverter.

ICs are fabricated in a series of stages, including a front-end-of-line (FEOL) stage, a middle-of-line (MOL) stage, and a back-end-of-line (BEOL) stage. The FEOL stage is where device elements (e.g., transistors) are patterned in the substrate/wafer. The MOL stage forms interconnect structures (e.g., lines, wires, metal-filled vias, contacts, and the like) that communicatively couple to active regions (e.g., gate, source, and drain) of the device element. Layers of interconnect structures are formed above these logical and functional layers during the BEOL stage to complete the IC.

Complementary metal oxide semiconductor (CMOS) technology is currently the dominant technology for the manufacture of inverters and other logic gates used in digital integrated circuits, including microprocessors, microcontrollers, or static random access memory (SRAM). The word “complementary” refers to the fact that a typical CMOS circuit may use complementary pairs of hole-type (positive) and electron-type (negative) FETs (field effect transistors), i.e., p-FETs and n-FETs, respectively. The n-FET uses electrons as the current carriers in combination with n-doped source and drain junctions. The p-FET uses holes as the current carriers in combination with p-doped source and drain junctions. CMOS technology can offer low static power consumption and high noise immunity, when compared to other digital technologies.

Semiconductor devices are typically formed using active regions of a wafer. In an IC having a plurality of metal oxide semiconductor field effect transistors (MOSFETs), each MOSFET has S/D regions that are formed in an active region of a semiconductor layer by incorporating n-type or p-type impurities in the layer of semiconductor material. A conventional MOSFET geometry is a non-planar FET known generally as a VTFET. VTFETs employ semiconductor fins and side-gates that can be contacted outside the active region, resulting in increased device density and some increased performance over lateral/planar devices. In VTFETs, the source-to-drain current flows in a direction that is perpendicular to a major surface of the substrate. For example, in a known VTFET configuration a major substrate surface is horizontal, and a vertical fin extends upward from the substrate surface. The fin forms the channel region of the transistor. A S/D region is situated in electrical contact with the top and bottom ends of the channel region, respectively, while a gate is disposed on one or more of the fin sidewalls.

ICs are designed by placing various cells with different functions. For example, cells can be logic gates, such as an AND gate, an OR gate, and the like, and combinational logic circuits such as an inverter, a multiplexer, a flip-flop, an adder, and a counter. Cells can be implemented to realize complex IC functions. For convenience of IC design, a library including frequently used cells with their corresponding layouts are established. Therefore, when designing an IC, a designer can select desired cells from the library and place the selected cell in an automatic placement and routing block, such that a layout of the IC can be created.

As semiconductor industry moves towards smaller nodes, for example 7-nm node and beyond, field-effect-transistors (FETs) are aggressively scaled in order to fit into the reduced footprint or real estate, which is often dictated by the node size, with increased device density. In addition, so-called backside power distribution networks (BSPDNs) have been introduced as a means to further enhance device density. Generally, a BSPDN provides power to a mixture of signal lines and power rails in the BEOL region of the wafer, and the power rails in turn provide the power from the BSPDN to active FEOL devices such as FETs.

An effective inverter design couples an S/D output of a first VTFET to a gate of second VTFET, where the two VTFETs are separated from one another by a single transistor gate pitch (also known as CPP or “contacted poly pitch”). Such inverter designs are known generally as single-CPP VTFET inverters. Although single-CPP VTFET inverters provide benefits, including improved (or reduced) wafer density, the output connection from the S/D output of one VTFET to the gate of the companion VTFET is very challenging. This is because, with the density of signal rails and power lines in the BEOL region, the relatively short distance from the S/D output of one VTFET to the gate of the companion VTFET in a single-CPP VTFET inverter configuration can require an actual signal path that moves up through a set of vertical levels, over, then downward through the same set of vertical levels to the gate of the second VTFET. It is common for the design of the contact that the connects the S/D to the adjacent VTFET's gate to traverse an up/over/down signal path that involves eight (8) or more level transitions within the IC wafer. Such an up/over/down contact path through so many levels carries an increase in resistance, which can be significant enough to at 7 nm node technology and beyond to degrade performance and require expensive and costly work around plans.

### SUMMARY

Embodiments of the invention provide a multi-layer integrated circuit (IC) structure that includes a first transistor, a second transistor, and a contact element. The first transistor includes a first source or drain (S/D). The second transistor includes a second S/D and a gate. The contact element includes substantially horizontal features operable to connect the first S/D of the first transistor to the gate of the second transistor.

The above-described features provide technical effects and benefits in that providing a contact element having substantially horizontal features enables providing a single-CPP VTFET inverter that provides benefits, including improved (or reduced) wafer density. Providing a contact element having substantially horizontal features further enables establishing a relatively small travel distance for signals to move from the S/D output of one VTFET to the gate of the companion VTFET in a single-CPP VTFET inverter configuration, which reduces contact resistance over contacts that require an up/over/down signal path through extending through multiple levels or layers of the IC structure.

In addition to one or more of the features described above, or as an alternative to any of the foregoing embodiments, the contact element is within one metallization layer of the IC structure.

The above-described features provide technical effects and benefits in that providing a contact element that is within one metallization layer of the IC structure enables providing a single-CPP VTFET inverter that provides benefits, including improved (or reduced) wafer density. Providing a contact element that is within one metallization layer of the IC structure further enables establishing a relatively small travel distance for signals to move from the S/D output of one VTFET to the gate of the companion VTFET in a single-CPP VTFET inverter configuration, which reduces contact resistance over contacts that require an up/over/down signal path through extending through multiple levels or layers of the IC structure.

Embodiments of the invention provide a method of forming a multi-layer integrated circuit (IC) structure that includes forming a first transistor, forming a second transistor, and forming a contact element having substantially horizontal features. The first transistor includes a first source or drain (S/D). The second transistor includes a second S/D and a gate. The contact element is operable to connect the first S/D of the first transistor to the gate of the second transistor.

The above-described features provide technical effects and benefits in that forming a contact element having substantially horizontal features enables providing a single-CPP VTFET inverter that provides benefits, including improved (or reduced) wafer density. Forming a contact element having substantially horizontal features further enables establishing a relatively small travel distance for signals to move from the S/D output of one VTFET to the gate of the companion VTFET in a single-CPP VTFET inverter configuration, which reduces contact resistance over contacts that require an up/over/down signal path through extending through multiple levels or layers of the IC structure.

In addition to one or more of the features described above, or as an alternative to any of the foregoing embodiments, the contact element is within one metallization layer of the IC structure.

The above-described features provide technical effects and benefits in that forming a contact element that is within one metallization layer of the IC structure enables providing a single-CPP VTFET inverter that provides benefits, including improved (or reduced) wafer density. Forming a contact element that is within one metallization layer of the IC structure further enables establishing a relatively small travel distance for signals to move from the S/D output of one VTFET to the gate of the companion VTFET in a single-CPP VTFET inverter configuration, which reduces contact resistance over contacts that require an up/over/down signal path through extending through multiple levels or layers of the IC structure.

In addition to one or more of the features described above, or as an alternative to any of the foregoing embodiments, forming the contact element includes using damascene fabrication operations and subtractive fabrication operations.

The above-described features provide technical effects and benefits in that forming a contact element that is within one metallization layer of the IC structure, and forming a contact element that is within one metallization layer of the IC structure can be implemented using reliable and established damascene fabrication operations and subtractive fabrication operations.

Additional technical features and benefits are realized through the techniques of the present invention. Embodiments and aspects of the invention are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the invention are apparent from the following detailed description taken in conjunction with the accompanying drawings in which:

FIG. 1 depicts a three-dimensional view of a portion of an IC wafer that incorporates aspects of the invention;

FIG. 2 depicts a set of vertical transport field effect transistors (VTFETs) in accordance with aspects of the invention;

FIG. 3A depicts a top-down cross-sectional view of a portion of the IC wafer shown in FIG. 1 illustrating a VTFET inverter after initial fabrication stages in accordance with aspects of the invention;

FIG. 3B depicts cross-sectional views of the VTFET inverter shown in FIG. 3A, taken along line X and line Y;

FIG. 4A depicts a top-down cross-sectional view of a portion of the IC wafer shown in FIG. 1 illustrating a VTFET inverter after subsequent fabrication stages in accordance with aspects of the invention;

FIG. 4B depicts cross-sectional views of the VTFET inverter shown in FIG. 4A, taken along line X and line Y;

FIG. 5A depicts a top-down cross-sectional view of a portion of the IC wafer shown in FIG. 1 illustrating a VTFET inverter after subsequent fabrication stages in accordance with aspects of the invention;

FIG. 5B depicts cross-sectional views of the VTFET inverter shown in FIG. 5A, taken along line X and line Y;

FIG. 6 depicts a frontside-down cross-sectional view of the IC wafer shown in FIG. 1, illustrating a configuration of signal lines in a BEOL region of the IC wafer;

FIG. 7 depicts a backside-up cross-sectional view of the IC wafer shown in FIG. 1, illustrating a configuration of power rails below an MOL region of the IC wafer.

FIG. 8 depicts process flows illustrating example methodologies for forming a low-resistance, single-metallization contact element in accordance with aspects of the invention; and

FIG. 9 depicts process flows illustrating example methodologies for forming a low-resistance, single-metallization contact element in accordance with aspects of the invention.

The diagrams depicted herein are illustrative. There can be many variations to the diagram or the operations described therein without departing from the spirit of the invention. For instance, the actions can be performed in a differing order or actions can be added, deleted or modified. Also, the term “coupled” and variations thereof describes having a communications path between two elements and does not imply a direct connection between the elements with no intervening elements/connections between them. All of these variations are considered a part of the specification.

In the accompanying figures and following detailed description of the described embodiments, the various elements illustrated in the figures are provided with two- or three-digit reference numbers. With minor exceptions, the leftmost digit(s) of each reference number correspond to the figure in which its element is first illustrated.

### DETAILED DESCRIPTION

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

Turning now to an overview of technologies that are more specifically relevant to aspects of the invention, semiconductor devices are used in a variety of electronic applications. ICs are typically formed from various circuit configurations of semiconductor devices (e.g., transistors, capacitors, resistors, etc.) and conductive interconnect layers (known as metallization layers) formed on semiconductor wafers. Alternatively, semiconductor devices can be formed as monolithic devices, e.g., discrete devices. Semiconductor devices and conductive interconnect layers are formed on semiconductor wafers by depositing many types of thin films of material over the semiconductor wafers, patterning the thin films, doping selective regions of the semiconductor wafers, etc.

In contemporary semiconductor fabrication processes, a large number of semiconductor devices and conductive interconnect layers are fabricated. More specifically, during the first portion of chip-making (i.e., the FEOL stage), the individual components (transistors, capacitors, etc.) are fabricated on the wafer. The MOL stage follows the FEOL stage and typically includes process flows for forming the contacts and other structures that communicatively couple to active regions (e.g., gate, source, and drain) of the device element. In the BEOL stage, these device elements are connected to each other through a network of interconnect structures to distribute signals, as well as power and ground. The conductive interconnect layers formed during the BEOL stage serve as a network of pathways that transport signals throughout an IC, thereby connecting circuit components of the IC into a functioning whole and to the outside world. Because there typically isn't enough room on the chip surface to create all of the necessary connections in a single layer, chip manufacturers build vertical levels of interconnects. While simpler ICs can have just a few metallization layers, complex ICs can have ten or more layers of wiring.

Semiconductor devices are typically formed using active regions of a wafer. In an IC having a plurality of metal oxide semiconductor field effect transistors (MOSFETs), each MOSFET has S/D regions that are formed in an active region of a semiconductor layer by incorporating n-type or p-type impurities in the layer of semiconductor material. A conventional MOSFET geometry is a non-planar FET known generally as a VTFET. VTFETs employ semiconductor fins and side-gates that can be contacted outside the active region, resulting in increased device density and some increased performance over lateral/planar devices. In VTFETs, the source-to-drain current flows in a direction that is perpendicular to a major surface of the substrate. For example, in a known VTFET configuration a major substrate surface is horizontal, and a vertical fin extends upward from the substrate surface. The fin forms the channel region of the transistor. A S/D region is situated in electrical contact with the top and bottom ends of the channel region, respectively, while a gate is disposed on one or more of the fin sidewalls.

As previously noted herein, ICs are designed by placing various cells with different functions. For example, cells can be logic gates, such as an AND gate, an OR gate, and the like, and combinational logic circuits such as a multiplexer, a flip-flop, an adder, and a counter. Cells can be implemented to realize complex IC functions. For convenience of IC design, a library including frequently used cells with their corresponding layouts are established. Therefore, when designing an IC, a designer can select desired cells from the library and place the selected cell in an automatic placement and routing block, such that a layout of the IC can be created.

As semiconductor industry moves towards smaller nodes, for example 7-nm node and beyond, field-effect-transistors (FETs) are aggressively scaled in order to fit into the reduced footprint or real estate, which is often dictated by the node size, with increased device density. In addition, so-called backside power distribution networks (BSPDNs) have been introduced as a means to further enhance device density. Generally, a BSPDN provides power to a mixture of signal lines and power rails in the BEOL region of the wafer, and the power rails in turn provide the power from the BSPDN to active FEOL devices such as FETs.

As previously noted, an effective inverter design couples an S/D output of a first VTFET to a gate of second VTFET, where the VTFETs are separate from one another by a single-CPP. Although single-CPP inverters using VTFETs improve wafer density, the output connection can require a path that moves up through a set of vertical levels, over, then downward through the same set of vertical levels to the gate of the second VTFET. Such an up/over/down path through multiple levels carries penalty of an increase in resistance (more specifically, an increase in contact resistance), which can be significant enough at 7 nm node technology and beyond to degrade performance and require expensive and costly work around plans.

Turning now to an overview of the aspects of the invention, embodiments of the invention address the difficulty in forming an inverter by coupling an S/D output of a first VTFET to a gate of second VTFET, where the VTFETs are separated from one another by a single-CPP, by forming the signal lines at one side of the wafer (e.g., in a BEOL region of the wafer) and forming the power rails at another side of the wafer (e.g., the backside of the wafer). By separating the signal lines from the power rails, the metallization density above in the BEOL region is sufficiently reduced to allow a more direct path for a contact that couples an S/D output of a first VTFET to a gate of second VTFET. In accordance with some embodiments of the invention the more direct path can occupy as single metallization layer with no metallization layer transitions.

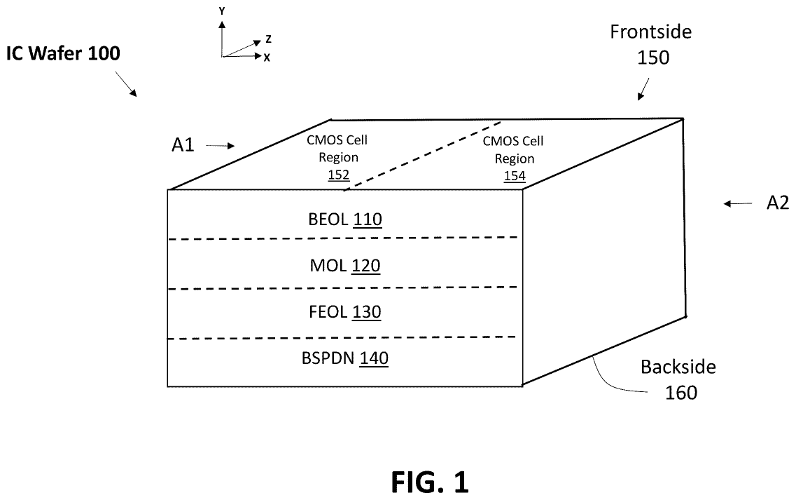

Turning now to a more detailed description of aspects of the present invention, FIG. 1 depicts a portion of an IC wafer 100 in accordance with aspects of the invention; The IC wafer 100 includes a middle-of-line (MOL) region 120 and a front-end-of-line (FEOL) region 130 positioned below a multi-layered BEOL region 110. The individual components (transistors, capacitors, etc.) and cell libraries are fabricated in the FEOL region 130. The MOL region 120 follows the FEOL region 130 and typically includes process flows for forming the contacts and other structures that communicatively couple to active regions (e.g., gate, source, and drain) of the device element. In the BEOL region 110, these device elements are connected to each other through a network of interconnect structures to distribute signals, as well as power and ground. The conductive interconnect layers formed during the BEOL region 110 serve as a network of pathways that transport signals throughout the IC wafer 100, thereby connecting circuit components of the IC wafer 100 into a functioning whole and to the outside world. Because there typically isn't enough room on the chip surface to create all of the necessary connections in a single layer, chip manufacturers build vertical levels of interconnects. While simpler IC wafers can have just a few metallization layers, complex ICs can have ten or more layers of wiring.

Interconnect structure in the BEOL region 110 that are physically close to components (e.g., transistors and the like) in the FEOL region 130 need to be small because they attach/join to the components that are themselves very small and often closely packed together. These lower-level lines, which can be referred to as local interconnects, are usually thin and short in length. Global interconnects are higher up in the structure of the IC wafer 100 and travel between different blocks of the circuit. Thus, global interconnects are typically thick, long, and more widely separated than local interconnects. Vertical connections between interconnect levels (or layers) are known as metal-filled vias and allow signals and power to be transmitted from one layer to the next. For example, a through-silicon via (TSV) is a conductive contact that passes completely through a given semiconductor wafer or die. In multi-layer IC configurations, for example, a TSV can be used to form vertical interconnections between a semiconductor device located on one layer/level of the IC and an interconnect layer located on another layer/level of the IC. These vertical interconnect structures include an appropriate metal and provide the electrical connection of the various stacked metallization layers.

As shown further shown in FIG. 1, the IC wafer 100 includes a frontside 150 and a backside 160. At the backside of the wafer is a BSPDN 140. The frontside 150 of the wafer 100 includes a CMOS cell region 152 and a CMOS cell region 154. In accordance with aspects of the invention, the CMOS cell regions 152, 154 include multiple cell libraries, and the cell libraries In the CMOS cell region 152 can have a different height than the cell libraries in the CMOS cell region 152. The notation A1 indicates a side view of the wafer 100 looking into the CMOS cell region 152. The notation A2 indicates a side view of the wafer 100 looking into the CMOS cell region 154.

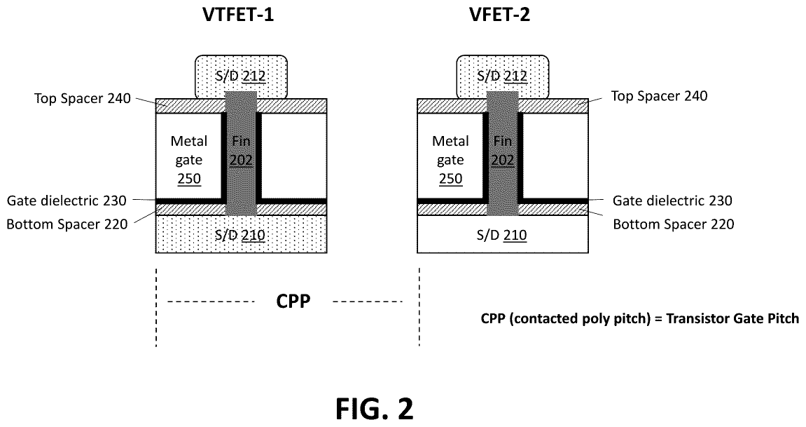

FIG. 2 depicts transistors that can be used to form the active devices of the cell regions (e.g., cell regions 152, 154 shown in FIG. 1). In FIG. 2, VTFET-1 and VTFET-2 are shown, although other suitable active devices can be used. Each of VTFET-1 and VT-FET-2 includes a bottom S/D region 210, a top S/D region 212, a channel fin 202, a gate dielectric 230, a metal gate 250, a bottom spacer 220, and a top spacer 240, configured and arranged as shown. Each of VTFET-1 and VTFET-2 employ a semiconductor channel fin 202 and a side-gate 250 that can be contacted outside the active region, resulting in increased device density and some increased performance over lateral/planar devices. In each of the VTFETs shown in FIG. 2, the source-to-drain current flows in a direction that is perpendicular to a major surface of the substrate (not shown). For example, in a known VTFET configuration a major substrate surface is horizontal, and a vertical fin (e.g., channel fin 202) extends upward from the substrate surface. The fin forms the channel region of the transistor. S/D regions 210, 212 are situated in electrical contact with the top and bottom ends of the channel region, respectively, while the gate 250 is disposed on one or more sidewalls of the channel fins 202.

FIG. 2 also illustrates the concept of CPP. As shown, CPP is the pitch from a point on one gate of a transistor to the corresponding point on an adjacent transistor. CPP can also be represented as the transistor gate pitch (TGP).

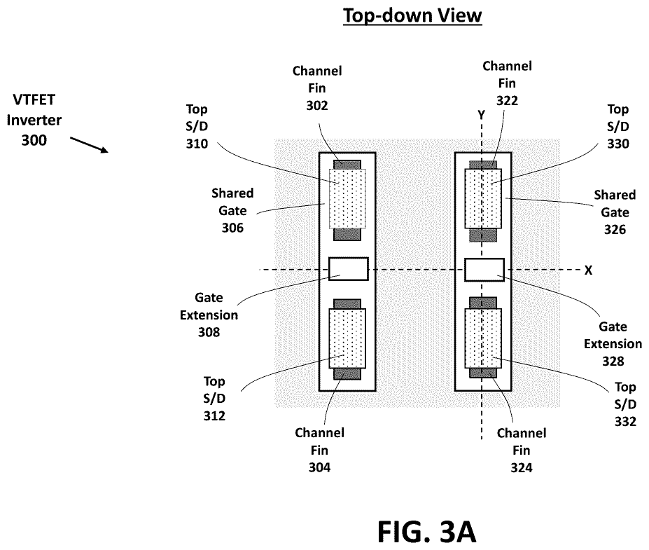

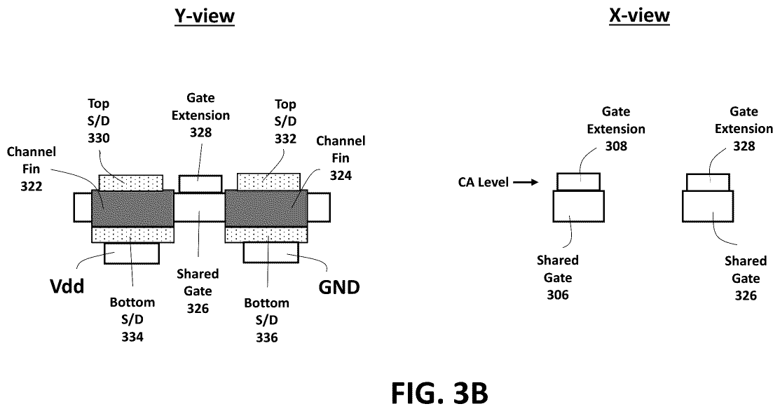

FIG. 3A depicts a top-down cross-sectional view of a portion of the IC wafer shown 100 in FIG. 1 illustrating a VTFET inverter 300 after initial fabrication stages in accordance with aspects of the invention. As shown, the VTFET inverter 300 includes a pair of first VTFETs separated by one-CPP from a second pair of VTFETs. Each pair of VTFETs is configured to share a common or shared gate 306, 326, respectively. Each of the leftmost VTFETs is configured to include substantially the same elements as the VTFET-1 or VTFET-2 shown in FIG. 2. In embodiments of the invention, each pair of the VTFETs includes an n-type VTFET and a p-type VTFET. FIG. 3B depicts cross-sectional views of the VTFET inverter 300 shown in FIG. 3A, taken along line X and line Y. As shown in FIGS. 3A and 3B, the leftmost pair of VTFETS includes channel fins 302, 304, a shared gate 306, a gate extension 308, bottom S/D regions (not shown), top S/D regions 310, 312, Vdd (not shown) and GND (ground) (not shown) coupled through the bottom S/D regions (not shown). Similarly, as shown in FIGS. 3A and 3B, the rightmost pair of VTFETS includes channel fins 322, 324, a shared gate 326, a gate extension 328, bottom S/D regions 334, 336, top S/D regions 330, 332, Vdd and GND coupled through the bottom S/D regions 334, 336. Known fabrication operations have been used to fabricate the VTFET inverter 300 to the stage shown in FIGS. 3A, 3B. The fabrication operations for forming the VTFET inverter 300 to the stage depicted in FIGS. 3A and 3B are well known so, for the sake of brevity, are not described in detail herein.

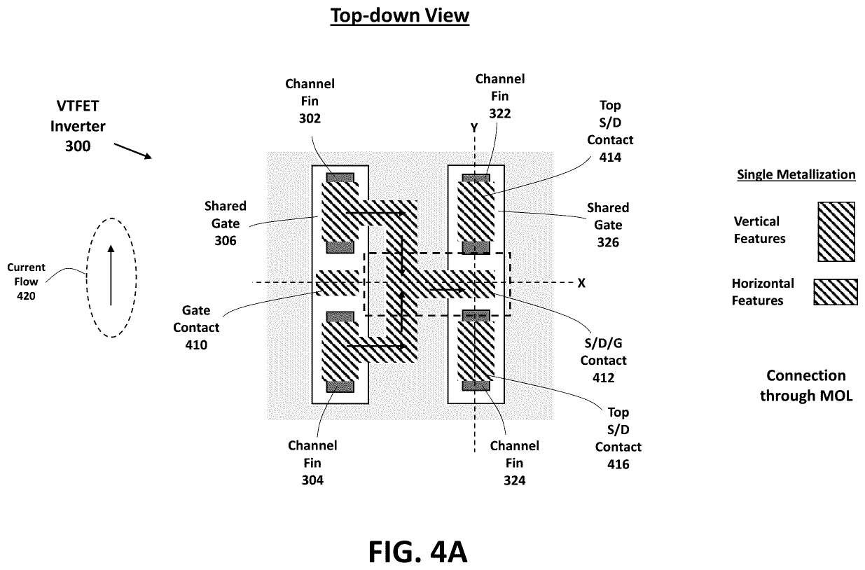

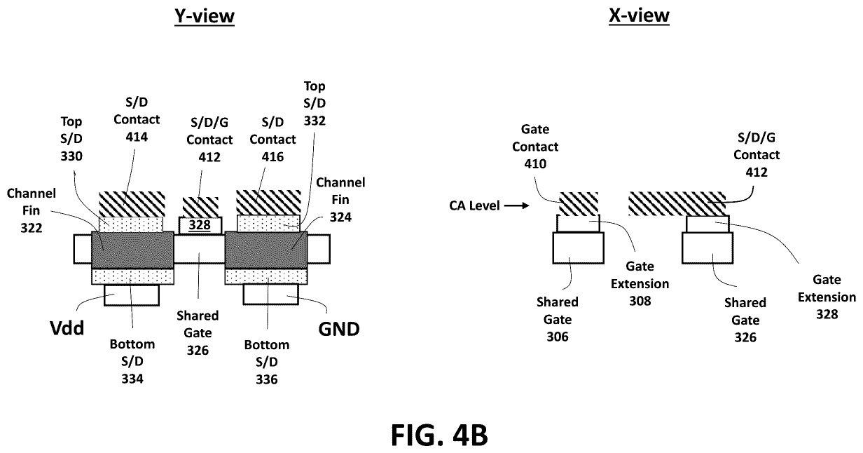

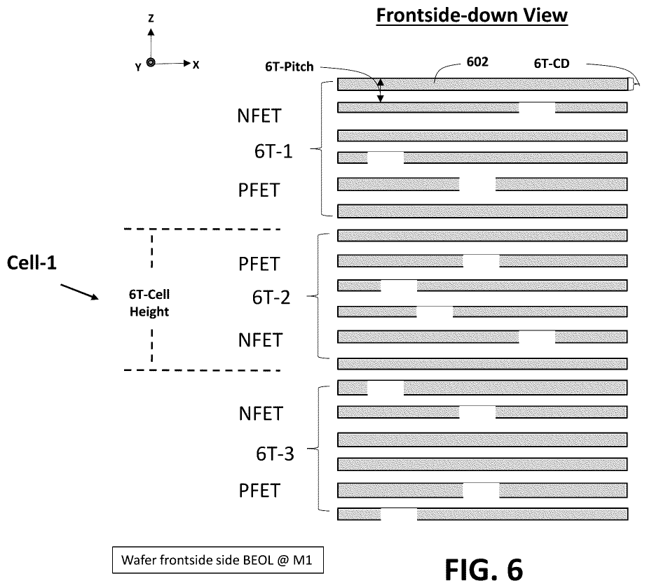

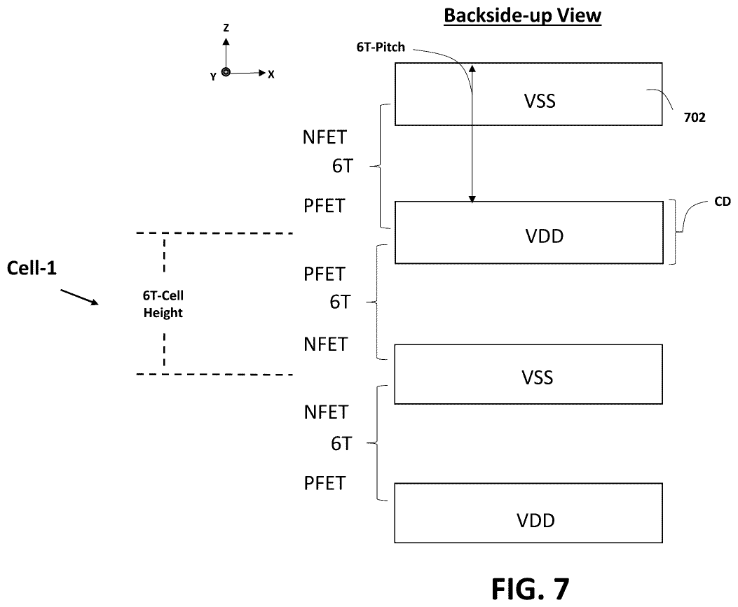

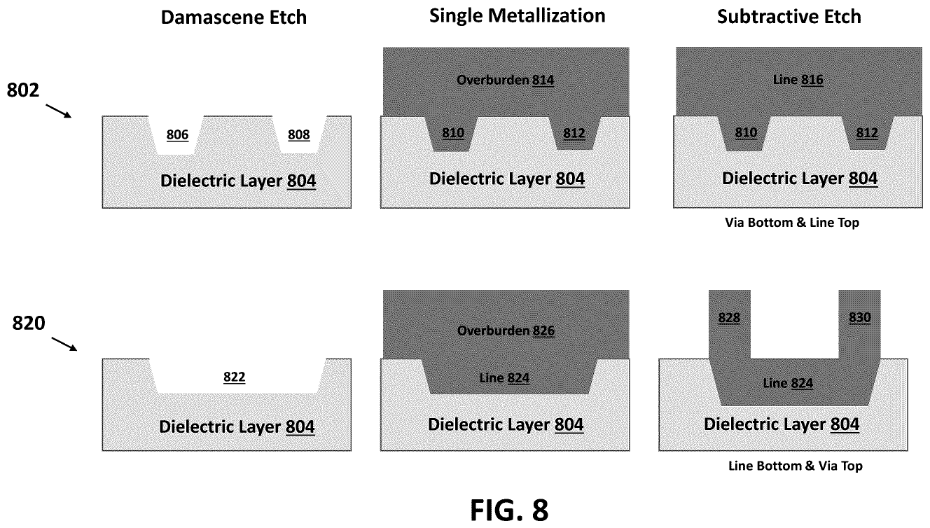

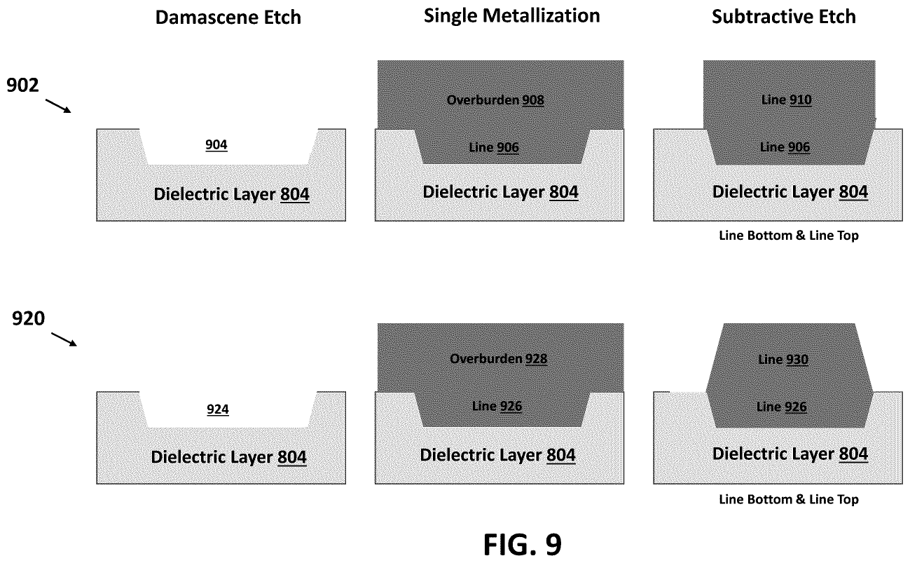

FIGS. 4A and 4B depict the VTFET inverter 300 after known fabrication operations (e.g., damascene fabrication operations and subtractive operations shown in FIGS. 8 and 9) have been performed to form a gate contact 410, top S/D contacts 414, 416, and a “S/D to gate” (S/D/G) contact element 412 operable to electronically couple the top S/D regions 310, 312 through the S/D/G contact element 412 to the shared gate 326, thereby functionalizing the VTFET inverter 300 to perform inverter operations. The direction of current flow 420 output from the top S/D regions 310, 312 (alone or in combination) through the SDG contact element 412 to the shared gate 326 is shown by directional arrows. In accordance with aspects of the invention, the difficulty in directly coupling the outputs from the top S/D regions 310, 312 to the shared gate 326 is mitigated by forming the signal lines 602 (shown in FIG. 6) at one side of the wafer (e.g., in a BEOL region 110 of the wafer 100 shown in FIG. 1) and forming the power rails 702 (shown in FIG. 7) at another side of the wafer (e.g., the backside 160 of the wafer 100 shown in FIG. 1). By separating the signal lines 602 from the power rails 702, the metallization density above in the BEOL region 110 is sufficiently reduced to allow a more direct path for the S/D/G contact element 412 to couple S/D outputs of the leftmost VTFET pair to the shared gate extension 328 of a rightmost VTFET pair. In accordance with embodiments of the invention the S/D/G contact element 412 occupies a single metallization layer (e.g., the CA layer shown in the X-view of FIG. 4B) with no metallization layer transitions.

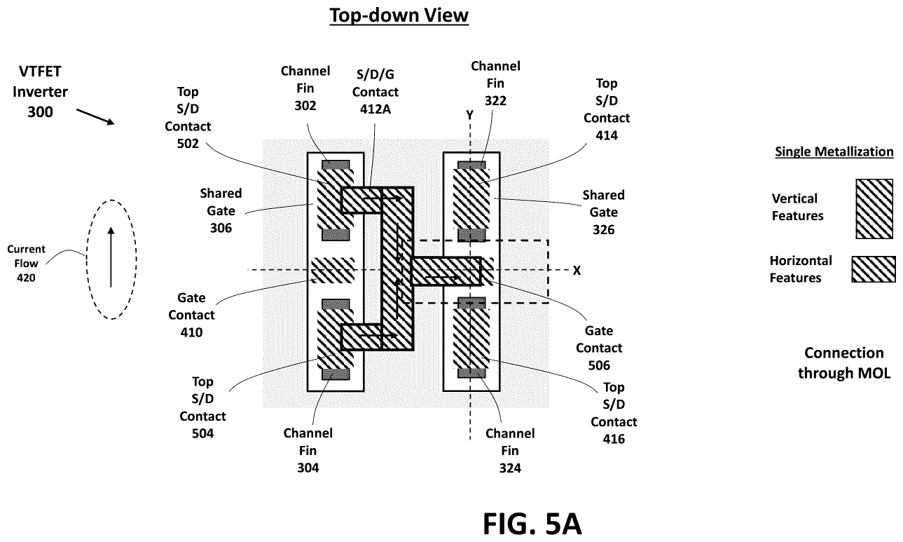

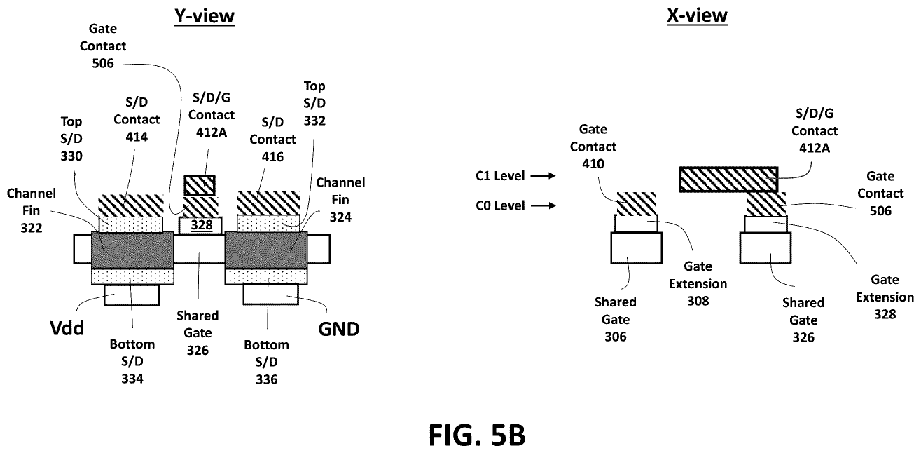

FIGS. 5A and 5B depict the VTFET inverter 300 after known fabrication operations (e.g., damascene fabrication operations and subtractive operations shown in FIGS. 8 and 9) have been performed to form top S/D contacts 502, 504, 414, 416, gate contacts 410, 506, and a S/D/G contact element 412A operable to electronically couple the top regions 310, 312 through the top S/D contacts 502, 504 and the S/D/G contact element 412A and the gate contact 510 to the shared gate 326, thereby functionalizing the VTFET inverter 300 to perform inverter operations. In some embodiments of the invention, substantially horizontal masks are used in the fabrication operations to form the top S/D contacts 502, 504, 414, 416 and the gate contacts 410, 506; and substantially vertical masks are used in the fabrication operations to form the S/D/G contact element 412A. The direction of current flow 420 output from the top S/D regions 302, 304 through the top S/D contacts 502, 504 and the SDG contact element 412A and the gate contact 506 to the shared gate 326 is shown by directional arrows. In accordance with aspects of the invention, the difficulty in directly coupling the outputs from the top S/D regions 310, 312 to the shared gate 326 is mitigated by forming the signal lines 602 (shown in FIG. 6) at one side of the wafer (e.g., in a BEOL region 110 of the wafer 100) and forming the power rails 702 (shown in FIG. 7) at another side of the wafer (e.g., the backside 160 of the wafer 100). By separating the signal lines 602 from the power rails 702, the metallization density above in the BEOL region 110 is sufficiently reduced to allow a more direct path for the S/D/G contact element 412 to couples an S/D output of a leftmost VTFET to the shared gate 328 of a rightmost VTFET. In accordance with embodiments of the invention, the contacts 502, 504, 410, 506 occupy a single metallization layer (e.g., the C0 layer shown in the X-view of FIG. 5B), and the S/D/G contact element 412A occupies a single metallization layer (e.g., the C1 layer shown in the X-view of FIG. 5B).

FIGS. 6 and 7 depict additional details of how signal lines 602 are separated from power rails 702, which declutters the BEOL region 110 and opens additional pathways for the S/D/G contact elements 412, 412A (shown in FIGS. 4A, 5A) to be formed in a single metallization layer. The height of a cell library can be measured by the total number of signal lines and/or power rails that are provided for the cell library. Each signal line 602 and each power rail 702 can be referred to as a track (T), and thus, cell height can be identified by the total number of cell tracks (T) associated with the cell library. A cell library that requires six (6) signal lines, ½ of a power rail at a first cell boundary, and ½ of a power rail at a second cell boundary, requires six (6) total tracks because the separated signal lines 602 and power rails 702 have overlap. Accordingly, such a cell library can be identified as a 6T cell. The width of signal lines 602 are each substantially uniform, and the width of power rails 702 are each substantially uniform and larger than the width of signal lines 602.

FIG. 6 depict a frontside-down view of the IC wafer 100 that depicts the signal lines 602 positioned in a lower layer (e.g., Ml) of the BEOL region 110 (shown in FIG. 1); and FIG. 7 depicts a backside-up view of the IC wafer 100 that depicts the power rails 702 positioned in a backside layer (e.g., Ml) at the backside 160 (shown in FIG. 1) of the BEOL region 110 (shown in FIG. 1). As shown in FIG. 6, the signal lines 602 have been formed having the 6T-CD (critical dimension, or width dimension), the 6T-Pitch, and corresponding to the 6T-Cell Height as shown in FIG. 6. As shown in FIG. 7, the power rails 702 have been formed having the 1T-CD (critical dimension, or width dimension), the 6T-Pitch, and corresponding to the 6T-Cell Height as shown in FIG. 7.

FIGS. 8 and 9 depict damascene processes 802, 820, 902, 920 that can be used to form the substantially horizontal S/D/G contact elements 412, 412A and/or the substantially vertical top S/D contacts 502, 504, 414, 416 and gate contacts 410, 506 in accordance with aspects of the invention. In general, damascene fabrication operations include depositing the dielectric layer 804 (e.g., over the VTFET inverter 300 shown in FIG. 3A), patterning and etching the dielectric layer to form openings 806, 808, 822, 904, 824, depositing metal within the openings 806, 808, 822, 904, 824 to fill the opening 806, 808, 822, 904, 824 and form overburdens 814, 826, 908, 928 on the etched dielectric layer 804. A subtractive etch is then applied to the overburdens 814, 826, 908, 928 to form final structures shown in FIGS. 8 and 9. For the methodology 802 shown in FIG. 8, the final structures include bottom vias 810, 812 and a line 816. For the methodology 820 shown in FIG. 8, the final structures include a bottom line 824 and top vias 828, 830. For the methodology 902 shown in FIG. 9, the final structures include bottom line 906 and a top 910. For the methodology 920 shown in FIG. 9, the final structures include a bottom line 926 and a top line 930, where the top line 930 is faceted in an opposite direction than the opening 924 and the bottom line 926.

Accordingly, it can be seen from the foregoing detailed description and accompanying figures that embodiments of the invention provide technical effects and benefits. Forming and/or providing a contact element having substantially horizontal features enables providing a single-CPP VTFET inverter that provides benefits, including improved (or reduced) wafer density. Providing/forming a contact element having substantially horizontal features further enables establishing a relatively small travel distance for signals to move from the S/D output of one VTFET to the gate of the companion VTFET in a single-CPP VTFET inverter configuration, which reduces contact resistance over contacts that require an up/over/down signal path through extending through multiple levels or layers of the IC structure.

In addition to one or more of the features described above, or as an alternative to any of the foregoing embodiments, the contact element is within one metallization layer of the IC structure. The above-described features provide technical effects and benefits in that providing/forming a contact element that is within one metallization layer of the IC structure enables providing a single-CPP VTFET inverter that provides benefits, including improved (or reduced) wafer density. Providing/forming a contact element that is within one metallization layer of the IC structure further enables establishing a relatively small travel distance for signals to move from the S/D output of one VTFET to the gate of the companion VTFET in a single-CPP VTFET inverter configuration, which reduces contact resistance over contacts that require an up/over/down signal path through extending through multiple levels or layers of the IC structure.

In addition to one or more of the features described above, or as an alternative to any of the foregoing embodiments, forming the contact element includes using damascene fabrication operations and subtractive fabrication operations. The above-described features provide technical effects and benefits in that forming a contact element that is within one metallization layer of the IC structure, and forming a contact element that is within one metallization layer of the IC structure can be implemented using reliable and established damascene fabrication operations and subtractive fabrication operations.

In addition to one or more of the features described above, or as an alternative to any of the foregoing embodiments, aspects of the invention further includes providing the contact element 412, 412A in an MOL connection as a single metallization; the contact element 412, 412A MOL connection connects to both the top S/D of the NFET and the top S/D of the PFET; the top S/D output(s) is an output signal; the MOL connection (e.g., the contact element 412, 412A) provides an output signal to the shared gate 326; the MOL connection can have upper and lower patterning features which are not aligned; the MOL connection can include damascene lower components and subtractive upper components; the MOL connection can be formed to a shared center gate region between the NFET and PFET devices; and patterning for MOL connection includes masking for vertical oriented features and separate masking for horizontal oriented features.

The methods and resulting structures described herein can be used in the fabrication of IC chips. The resulting IC chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes IC chips, ranging from toys and other low-end applications to advanced computer products having a display, a keyboard or other input device, and a central processor.

Various embodiments of the present invention are described herein with reference to the related drawings. Alternative embodiments can be devised without departing from the scope of this invention. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e., one, two, three, four, etc. The terms “a plurality” are understood to include any integer number greater than or equal to two, i.e., two, three, four, five, etc. The term “connection” can include an indirect “connection” and a direct “connection.”

References in the specification to “one embodiment,” “an embodiment,” “an example embodiment,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

Spatially relative terms, e.g., “beneath,” “below,” “lower,” “above,” “upper,” and the like, can be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device can be otherwise oriented (rotated 90 degrees or at other orientations) and the spatially relative descriptors used herein interpreted accordingly.

“Planarization” and “planarize” as used herein refer to a material removal process that employs at least mechanical forces, such as frictional media, to produce a substantially two-dimensional surface. A planarization process can include chemical mechanical polishing (CMP) or grinding. CMP is a material removal process that uses both chemical reactions and mechanical forces to remove material and planarize a surface.

The phrase “selective to,” such as, for example, “a first element selective to a second element,” means that the first element can be etched and the second element can act as an etch stop.

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

The term “conformal” (e.g., a conformal layer) means that the thickness of the layer is substantially the same on all surfaces, or that the thickness variation is less than 15% of the nominal thickness of the layer.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases can be controlled and the system parameters can be set so that the depositing atoms arrive at the deposition surface of the semiconductor substrate with sufficient energy to move about on the surface such that the depositing atoms orient themselves to the crystal arrangement of the atoms of the deposition surface. An epitaxially grown semiconductor material can have substantially the same crystalline characteristics as the deposition surface on which the epitaxially grown material is formed. For example, an epitaxially grown semiconductor material deposited on a 11001 orientated crystalline surface can take on a 11001 orientation. In some embodiments of the invention, epitaxial growth and/or deposition processes can be selective to forming on semiconductor surface, and cannot deposit material on exposed surfaces, such as silicon dioxide or silicon nitride surfaces.

As previously noted herein, for the sake of brevity, conventional techniques related to semiconductor device and IC fabrication may or may not be described in detail herein. By way of background, however, a more general description of the semiconductor device fabrication processes that can be utilized in implementing one or more embodiments of the present invention will now be provided. Although specific fabrication operations used in implementing one or more embodiments of the present invention can be individually known, the described combination of operations and/or resulting structures of the present invention are unique. Thus, the unique combination of the operations described in connection with the fabrication of a semiconductor device according to the present invention utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), chemical-mechanical planarization (CMP), and the like. Reactive ion etching (RIE), for example, is a type of dry etching that uses chemically reactive plasma to remove a material, such as a masked pattern of semiconductor material, by exposing the material to a bombardment of ions that dislodge portions of the material from the exposed surface. The plasma is typically generated under low pressure (vacuum) by an electromagnetic field. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The flowchart and block diagrams in the Figures illustrate possible implementations of fabrication and/or operation methods according to various embodiments of the present invention. Various functions/operations of the method are represented in the flow diagram by blocks. In some alternative implementations, the functions noted in the blocks can occur out of the order noted in the Figures. For example, two blocks shown in succession can, in fact, be executed substantially concurrently, or the blocks can sometimes be executed in the reverse order, depending upon the functionality involved.

The descriptions of the various embodiments of the present invention have been presented for purposes of illustration but are not intended to be exhaustive or limited to the embodiments described. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A multi-layer integrated circuit (IC) structure comprising:
a first transistor having a first source or drain (S/D);
a second transistor having a second S/D and a gate; and
a contact element having substantially horizontal features operable to connect the first S/D of the first transistor to the gate of the second transistor.

2. The IC structure of claim 1, wherein the contact element is within one metallization layer of the IC structure.

3. The IC structure of claim 2, wherein the contact element is in a middle-of-line (MOL) region of the IC structure.

4. The IC structure of claim 1, wherein:
the first transistor comprises a first n-type field effect transistor (NFET), a first p-type FET (PFET), and a first shared gate; and
the first S/D region comprises:
a S/D region of the first NFET; and
a S/D region of the first PFET.

5. The IC structure of claim 4, wherein:
the second transistor comprises a second NFET, a second PFET, and a second shared gate; and
the gate comprises the second shared gate.

6. The IC structure of claim 5, wherein the contact element connects:
the S/D region of the first NFET;
the S/D region of the first PFET; and
the second shared gate.

7. The IC structure of claim 1 further comprising an inverter comprising the first transistor and the second transistor.

8. The IC structure of claim 7, wherein:
the first transistor comprises a first vertical transport field effect transistor (VTFET);
the second transistor comprises a second VTFET; and
the first VTFET is separated from the second VTFET by one transistor gate pitch.

9. The IC structure of claim 8 further comprising:
a S/D contact in electrical contact with the first S/D, wherein the S/D contact is within a first metallization level; and
a gate contact in electrical contact with the gate, wherein the gate contact is within the first metallization level.

10. The IC structure of claim 9, wherein:
the contact element electrically couples to the first S/D through the S/D contact;
the contact element electrically couples to the gate through the gate contact; and
the one metallization level is adjacent the first metallization level.

11. A method of forming a multi-layer integrated circuit (IC) structure, the method comprising:
forming a first transistor having a first source or drain (S/D);
forming a second transistor having a second S/D and a gate; and
forming a contact element having substantially horizontal features operable to connect the first S/D of the first transistor to the gate of the second transistor.

12. The method of claim 11, wherein the contact element is within one metallization layer of the IC structure.

13. The method of claim 12, wherein the contact element is formed in a middle-of-line (MOL) region of the IC structure.

14. The method of claim 11, wherein:
the first transistor comprises a first n-type field effect transistor (NFET), a first p-type FET (PFET), and a first shared gate;
the first S/D region comprises:
a S/D region of the first NFET; and
a S/D region of the first PFET;
the second transistor comprises a second NFET, a second PFET, and a second shared gate; and
the gate comprises the second shared gate.

15. The method of claim 14, wherein the contact element connects:
the S/D region of the first NFET;
the S/D region of the first PFET; and
the second shared gate.

16. The method of claim 11, wherein forming the contact element comprises using damascene fabrication operations and subtractive fabrication operations.

17. The method of claim 11, wherein forming the contact element comprises:
using vertically oriented masking to form substantially vertical features of the contact element; and
using horizontally oriented masking to form the substantially horizontal features of the contact element.

18. The method of claim 11, wherein forming the first transistor and forming the second transistor forms an inverter.

19. The method of claim 18, wherein:
the first transistor comprises a first vertical transport field effect transistor (VTFET);
the second transistor comprise a second VTFET; and
the first VTFET is separated from the second VTFET by one transistor gate pitch.

20. The method of claim 19 further comprising:
forming a S/D contact in electrical contact with the first S/D, wherein the S/D contact is within a first metallization level; and
forming a gate contact in electrical contact with the gate, where in the gate contact is within the first metallization level;
wherein the contact element electrically couples to the S/D through the S/D contact;
wherein the contact element electrically couples to the gate contact through the gate contact; and
wherein the one metallization level is adjacent the first metallization level.
